(19) United States
(12) Patent Application Publication
(10) Pub. No.: US 2019/0013121 A1
(43) Pub. Date: Jan. 10, 2019

(54) MULTILAYER BEAD AND BOARD HAVING THE SAME

(71) Applicant: SAMSUNG ELECTRO-MECHANICS CO., LTD., Suwon-si (KR)

(72) Inventors: Young Jin HA, Suwon-si (KR); Jeong Hwan IM, Suwon-si (KR); So Young JUN, Suwon-si (KR); Sung Jin PARK, Suwon-si (KR)

(21) Appl. No.: 15/824,947

(22) Filed: Nov. 28, 2017

(30) Foreign Application Priority Data
Jul. 4, 2017 (KR) 10-2017-0084712

(51) Int. Cl. H01C 13/02; H01F 17/00; H01C 7/02; H05K 1/18; H01F 27/29

(52) U.S. Cl. CPC H01C 13/02; H01F 17/0013; H01F 2017/0066; H05K 1/181; H01F 27/292; H01C 7/023

(57) ABSTRACT

A multilayer bead includes a body in which a plurality of ceramic layers are stacked; a plurality of internal electrode patterns formed on the plurality of ceramic layers; and first and second external electrodes formed on both end surfaces of the body and electrically connected to both ends of an internal coil formed by a combination of the plurality of internal electrode patterns, respectively. A stacking direction of the plurality of ceramic layers is parallel to both end surfaces of the body on which the first and second external electrodes are formed, and a coil axis of the internal coil is parallel to a mounting surface of the body. A board having the multilayer bead may be provided.

### CROSS-REFERENCE TO RELATED APPLICATION

This application claims benefit of priority to Korean Patent Application No. 10-2017-0084712 filed on Jul. 4, 2017 in the Korean Intellectual Property Office, the disclosure of which is incorporated herein by reference in its entirety.

### BACKGROUND

### 1. Field

The present disclosure relates to a multilayer bead and a board having the same.

### 2. Description of Related Art

Generally, a bead, an element having the characteristics of a resistor, in addition to the characteristics of an inductor, exhibits high resistance characteristics in a high frequency band, such that the bead absorbs energy of a high-frequency component to convert the energy to heat. In a chip bead, impedance is commonly implemented by using a magnetic ferritic material as a main ingredient and forming a coil using silver (Ag) paste, or the like, therein.

Meanwhile, recently, in accordance with the increased speed and multi-functionalization of digital devices such as mobile phones, and the like, the number of components mounted therein has increased, and thus, a mounting density of components has also increased. As mounting density is increased, an interval between the components is also decreased, and thus, electromagnetic interference (EMI) between the components should be considered.

As the interval between the components is decreased, magnetic flux generated in a chip bead used to remove EMI noise has an influence on other peripheral components, such that malfunctions may occur, or other components may not fulfill their intended functions.

### SUMMARY

An aspect of the present disclosure may provide a multilayer bead capable of significantly decreasing an influence on peripheral components by controlling a direction of magnetic flux, while having excellent direct current resistance (DCR) characteristics, and a board having the same.

According to an aspect of the preset disclosure, a multilayer bead may include: a body in which a plurality of ceramic layers are stacked; a plurality of internal electrode patterns formed on the plurality of ceramic layers; and first and second external electrodes formed on both end surfaces of the body and electrically connected to both ends of an internal coil formed by a combination of the plurality of internal electrode patterns, respectively, wherein a stacking direction of the plurality of ceramic layers is parallel to both end surfaces of the body on which the first and second external electrodes are formed, and a coil axis of the internal coil is parallel to a mounting surface of the body.

According to another aspect of the present disclosure, a board having a multilayer bead may include: a circuit board on which a plurality of electrode pads are formed; and the multilayer bead mounted so as to be electrically connected to the electrode pads, wherein the multilayer bead includes: a body in which a plurality of ceramic layers are stacked; a plurality of internal electrode patterns are formed on the plurality of ceramic layers; and first and second external electrodes formed on both end surfaces of the body and electrically connected to both ends of an internal coil formed by a combination of the plurality of internal electrode patterns, respectively, a stacking direction of the plurality of ceramic layers being parallel to both end surfaces of the body on which the first and second external electrodes are formed, and a coil axis of the internal coil being mounted parallel to amounting surface of the body.

### BRIEF DESCRIPTION OF DRAWINGS

The above and other aspects, features, and advantages of the present disclosure will be more clearly understood from the following detailed description taken in conjunction with the accompanying drawings, in which:

FIG. 1 shows a perspective view schematically illustrating a multilayer bead according to an exemplary embodiment in the present disclosure;

FIG. 2 shows a partially cut-away perspective view illustrating the multilayer bead of FIG. 1;

FIG. 3 shows a cross-sectional view taken along line I-I′ of FIG. 2;

FIG. 4 shows a case in which a multilayer bead according to the related art and an inductor are adjacently disposed;

FIGS. 5A and 5B show cross-sectional views taken along line II-II′ of FIG. 4;

FIG. 6 shows a case in which a multilayer bead according to the exemplary embodiment in the present disclosure and an inductor are adjacently disposed;

FIGS. 7A and 7B show cross-sectional views taken along line of FIG. 6; and

FIG. 8 show a perspective view schematically illustrating a board on which the multilayer bead according to an exemplary embodiment in the present disclosure is mounted.

### DETAILED DESCRIPTION

Hereinafter, exemplary embodiments of the present disclosure will now be described in detail with reference to the accompanying drawings.

Hereinafter, a multilayer bead according to an exemplary embodiment in the present disclosure will be described in detail.

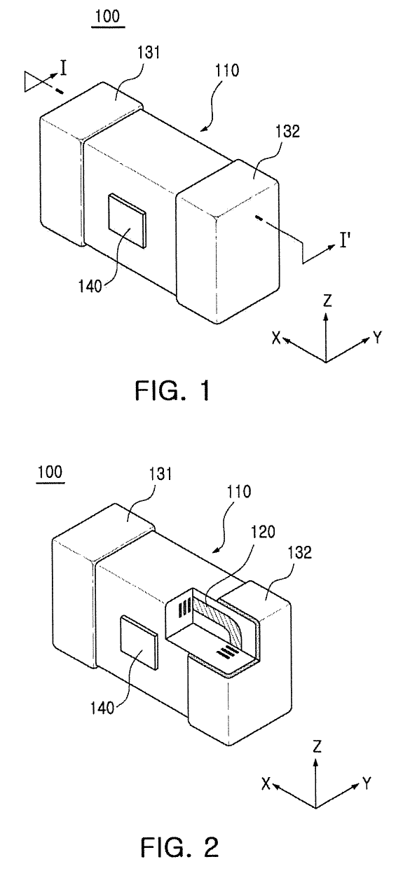

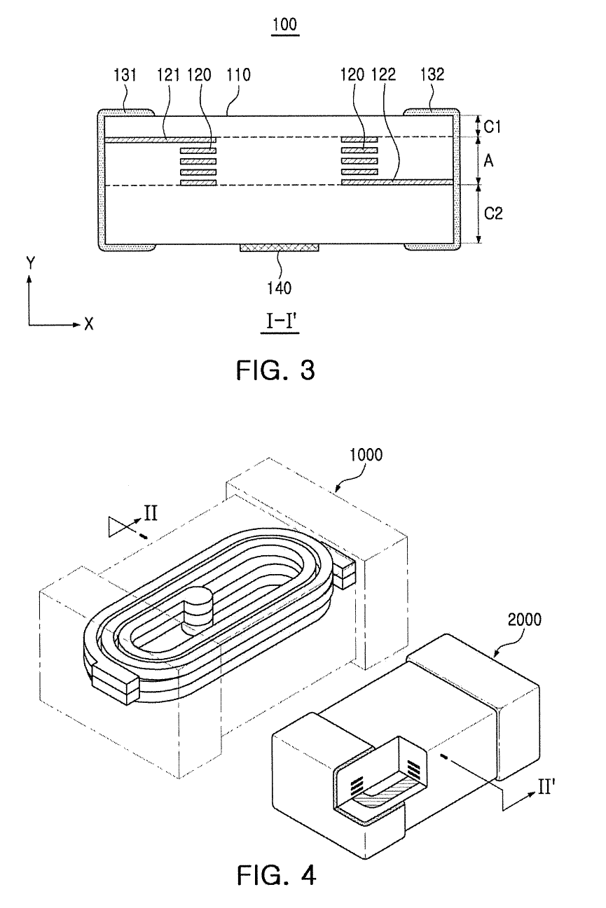

FIG. 1 shows a perspective view schematically illustrating a multilayer bead according to an exemplary embodiment in the present disclosure, FIG. 2 shows a partially cut-away perspective view illustrating the multilayer bead of FIG. 1, and FIG. 3 shows a cross-sectional view taken along line I-I′ of FIG. 2.

Referring to FIGS. 1 through 3, a multilayer bead 100 according to the exemplary embodiment in the present disclosure may include a body 110 in which a plurality of ceramic layers are stacked; a plurality of internal electrode patterns 120 formed on the plurality of ceramic layers; and first and second external electrodes 131 and 132 formed on both end surfaces of the body and electrically connected to both ends of an internal coil formed by a combination of the plurality of internal electrode patterns, respectively.

A shape of the body 110 is not particularly limited, but the body 110 may have, for example, a hexahedral shape.

Directions of a hexahedron will be defined in order to clearly describe the exemplary embodiment in the present disclosure. X, Y and Z, illustrated in FIG. 1, refer to a length direction, a width direction, and a thickness direction, respectively. Here, the ‘width direction’ is the same as the direction in which ceramic layers are stacked, that is, a ‘stacking direction’.

The plurality of ceramic layers may be in a sintered state, and adjacent ceramic layers may be integrated with each other so that boundaries therebetween are not readily apparent without using a scanning electron microscope (SEM).

Each of the plurality of ceramic layers may contain a ferrite known in the art such as a Mn—Zn based ferrite, a Ni—Zn based ferrite, a Ni—Zn—Cu based ferrite, a Mn—Mg based ferrite, a Ba based ferrite, a Li based ferrite, or the like.

An internal electrode pattern 120 may be formed on one surface of each of the ceramic layers. The internal electrode patterns 120 may be combined with respect to the width direction by stacking a plurality of ceramic layers on which the internal electrode pattern 120 is formed, such that the internal coil may be formed through the internal coil patterns 120 combined as described above.

The internal electrode pattern 120 may be formed of a metal having excellent electrical conductivity. For example, the internal electrode pattern 120 may be formed of silver (Ag), palladium (Pd), aluminum (Al), nickel (Ni), titanium (Ti), gold (Au), copper (Cu), platinum (Pt), or an alloy thereof, etc., but is not necessarily limited thereto.

The internal electrode pattern 120 may be formed by printing a conductive paste containing the conductive metal on the ceramic layer. However, a method of forming the internal electrode pattern 120 is not necessarily limited thereto, but another method known in the art may also be used as long as an effect similar to the above-mentioned effect is obtained.

The body 110 may include an active layer A corresponding to a capacitance formation portion, and a first cover layer C1 formed on an upper portion of the active layer A in the thickness direction, and a second cover layer C2 formed on a lower portion of the active layer A in the thickness direction.

The first and second cover layers C1 and C2 may be foliated by sintering a plurality of ceramic layers commonly to the active layer A. Further, the plurality of ceramic layers included in the first and second cover layers C1 and C2 may be in a sintered state, and adjacent ceramic layers may be integrated with each other so that boundaries therebetween are not readily apparent without using a scanning electron microscope, similarly to the active layer A.

The first and second external electrodes 131 and 132 may serve to electrically connect a coil component to a circuit board, or the like when the coil component is mounted on the circuit board, or the like. Further, the first and second external electrodes 131 and 132 may be formed on both end surfaces of the body in the length direction to thereby be electrically connected to both ends of the internal coil formed by the combination of the plurality of internal electrode patterns 120.

The first and second external electrodes 131 and 132 may be formed of a metal having excellent electric conductivity. For example, the first and second external electrodes 131 and 132 may be formed of silver (Ag), palladium (Pd), aluminum (Al), nickel (Ni), titanium (Ti), gold (Au), copper (Cu), platinum (Pt), or an alloy thereof, etc.

A method of forming the first and second external electrodes 131 and 132 and specific shapes of the first and second external electrodes 131 and 132 are not particularly limited. For example, the first and second external electrodes 131 and 132 may be formed to have a cross-sectional shape of an alphabet C shape along x direction using a dipping method.

Referring to FIG. 3, the stacking direction of the plurality of ceramic layers may be perpendicular to both end surfaces of the body on which the first and second external electrodes 131 and 132 are formed. Generally, a plurality of ceramic layers may be stacked in a direction parallel to or perpendicular to both end surfaces of a body in a length direction (i.e. x direction). In a case in which the plurality of ceramic layers are stacked in the direction parallel to both end surfaces of the body, the number of stacked ceramic layers may be relatively increased, and direct current resistance (DCR) characteristics may be deteriorated. However, according to the present disclosure, the stacking direction (i.e. y direction) of the plurality of ceramic layers may be parallel to both end surfaces of the body, such that the number of stacked ceramic layers may be relatively decreased, and direct current resistance (DCR) characteristics may be excellent.

Referring to FIG. 2, a coil axis of the internal coil formed by the combination of the plurality of internal electrode patterns may be parallel to a lower surface of the body 110 corresponding to a mounting surface. Therefore, the multilayer bead according to the exemplary embodiment in the present disclosure may have an advantage in that a mutual magnetic flux influence with peripheral components is small.

Hereinafter, this advantage will be described in detail with reference to the accompanying drawings.

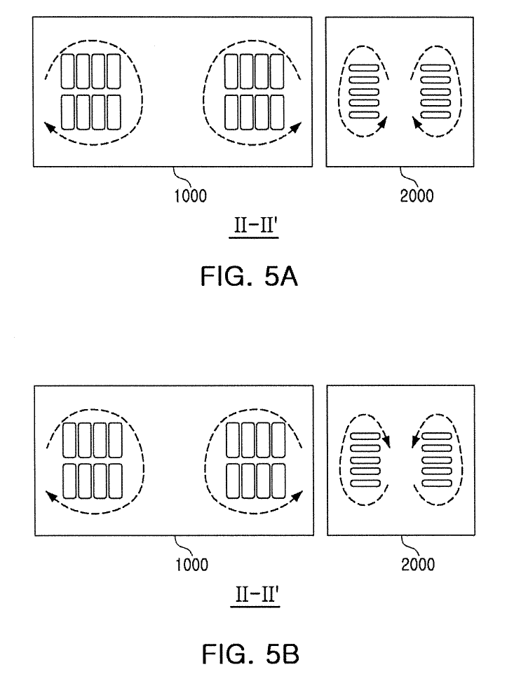

FIG. 4 shows a case in which a multilayer bead 2000 according to the related art and an inductor 1000 are adjacently disposed, and FIGS. 5A and 5B show cross-sectional views taken along line II-II′ of FIG. 4.

FIG. 5A shows a case in which a direction of magnetic flux generated in the inductor 1000 and a direction of magnetic flux generated in the multilayer bead 2000 are equal to each other. In this case, malfunctions may occur. FIG. 5B shows a case in which the direction of the magnetic flux generated in the inductor 1000 and the direction of the magnetic flux generated in the multilayer bead 2000 are different from each other. In this case, the magnetic fluxes may be offset with each other, such that the multilayer bead 2000 may not fulfill its functions.

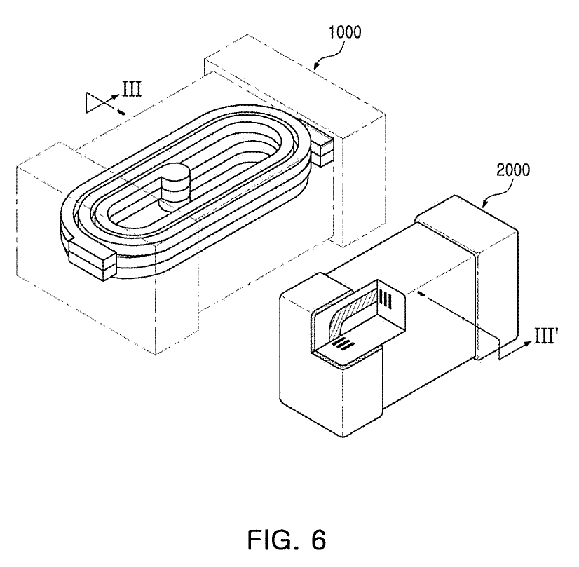

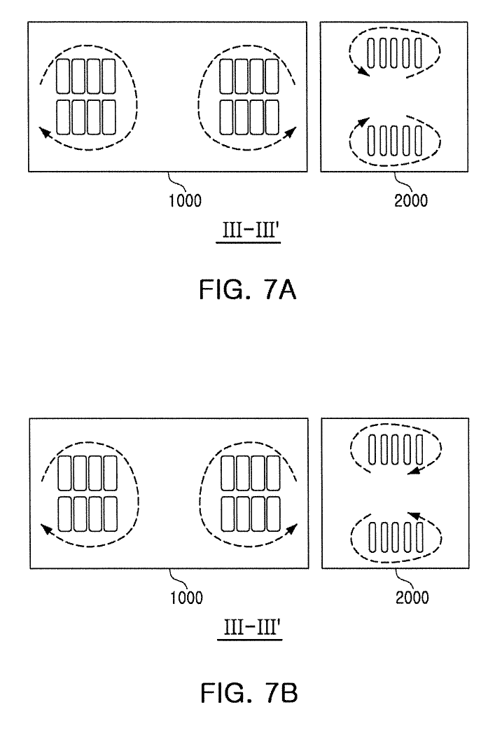

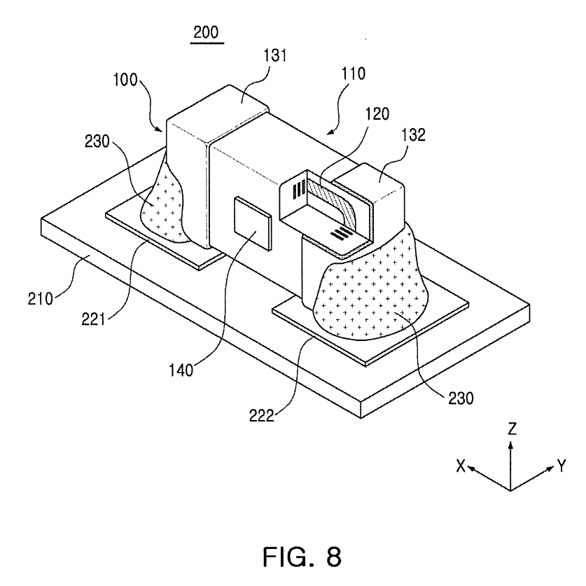

FIG. 6 shows a case in which a multilayer bead 2000 according to the exemplary embodiment in the present disclosure and an inductor 1000 are adjacently disposed, and FIGS. 7A and 7B show cross-sectional views taken along line III-III′ of FIG. 6.

Referring to FIGS. 7A and 7B, it may be visually confirmed that in the multilayer bead 2000 according to the present disclosure, the coil axis of the inductor 1000 and the coil axis of the adjacently disposed multilayer bead 2000 are non-parallel with each other, and the mutual magnetic flux influence with peripheral components may be decreased regardless of a direction of magnetic flux generated in the multilayer bead 2000.

According to the exemplary embodiment, in order to easily distinguish the mounting surface of the body 110, a marking pattern 140 may be provided on at least one surface of the body 110.

In this case, in order to easily distinguish the marking pattern 140, a color of the marking pattern 130 may be different from that of the body 110, and unevenness may be formed on a surface of the marking pattern 140, but the marking pattern 140 is not necessarily limited thereto.

The marking pattern 140 may be provided on at least one of two outermost ceramic layers disposed in outermost positions of the body 110 among the plurality of ceramic layers stacked in the body 110. In this case, it may be easy to form the marking pattern.

The marking pattern 140 may be provided on any one of two outermost ceramic layers disposed in outermost positions of the body 110 among the plurality of ceramic layers stacked in the body 110. In this case, a minimum separation distance C2 between the internal coil and an outermost ceramic layer on which the marking pattern is provided may be greater than a minimum separation distance C1 between the internal coil and an outermost ceramic layer on which the marking pattern is not provided. In a case in which C1 and C2 are different from each other as described above, the internal coil of the multilayer bead may be disposed to be more distant from peripheral components, such that the mutual magnetic flux influence with the peripheral components may be more effectively decreased.

Hereinafter, a board having a multilayer bead according to another exemplary embodiment in the present disclosure will be described in detail.

FIG. 8 shows a perspective view schematically illustrating a board on which the multilayer bead according to an exemplary embodiment in the present disclosure is mounted.

Referring to FIG. 8, the board 200 having a multilayer bead according to another exemplary embodiment in the present disclosure may include a circuit board 210 on which the multilayer bead 100 is mounted, and a plurality of electrode pads 221 and 222 fanned on one surface of the circuit board 210 to be spaced apart from each other. Here, the multilayer bead 100 may be electrically connected to the circuit board 210 by soldering 230 in a state in which the external electrodes 131 and 132 are positioned to contact the plurality of electrode pads 221 and 222, respectively.

In the board 200 having a multilayer bead 100 according to another exemplary embodiment in the present disclosure, a coil axis of an internal coil of a multilayer bead 100 may be mounted parallel to a mounting surface of a body. In a case in which the coil axis of the internal coil of the multilayer bead 100 is mounted parallel to the mounting surface of the body as described above, there is an advantage in that a mutual magnetic flux influence with peripheral components may be small.

A description for features overlapping those of the multilayer bead according to the exemplary embodiment in the present disclosure described above except for the above-mentioned description will be omitted.

As set forth above, according to exemplary embodiments in the present disclosure, the multilayer bead has advantages in that the direction current resistance (DCR) characteristics are excellent, and a mutual magnetic flux influence with peripheral components is small.

While exemplary embodiments have been shown and described above, it will be apparent to those skilled in the art that modifications and variations could be made without departing from the scope of the present disclosure as defined by the appended claims.

What is claimed is:

1. A multilayer bead comprising:
a body in which a plurality of ceramic layers are stacked;
a plurality of internal electrode patterns formed on the plurality of ceramic layers; and
first and second external electrodes formed on both end surfaces of the body and electrically connected to both ends of an internal coil formed by a combination of the plurality of internal electrode patterns, respectively,
wherein a stacking direction of the plurality of ceramic layers is perpendicular to both end surfaces of the body on which the first and second external electrodes are formed, and
a coil axis of the internal coil is parallel to a mounting surface of the body.

2. The multilayer bead of claim 1, wherein a marking pattern is provided on at least one surface of the body.

3. The multilayer bead of claim 2, wherein the marking pattern is provided on at least one of two outermost ceramic layers disposed in outermost positions of the body among the plurality of ceramic layers stacked in the body.

4. The multilayer bead of claim 2, wherein the marking pattern is provided on any one of two outermost ceramic layers disposed in outermost positions of the body among the plurality of ceramic layers stacked in the body, and a minimum separation distance between the internal coil and an outermost ceramic layer on which the marking pattern is provided is greater than a minimum separation distance between the internal coil and an outermost ceramic layer on which the marking pattern is not provided.

5. The multilayer bead of claim 2, wherein a color of the marking pattern is different from that of the body.

6. The multilayer bead of claim 2, wherein unevenness is formed on a surface of the marking pattern.

7. The multilayer bead of claim 1, wherein the ceramic layers contain ferrite.

8. A board having a multilayer bead, the board comprising:
a circuit board on which a plurality of electrode pads are formed; and
the multilayer bead mounted and electrically connected to the electrode pads,
wherein the multilayer bead includes:
a body in which a plurality of ceramic layers are stacked;
a plurality of internal electrode patterns formed on the plurality of ceramic layers; and
first and second external electrodes formed on both end surfaces of the body and electrically connected to both ends of an internal coil formed by a combination of the plurality of internal electrode patterns, respectively,
a stacking direction of the plurality of ceramic layers being perpendicular to both end surfaces of the body on which the first and second external electrodes are formed, and
a coil axis of the internal coil being mounted parallel to a mounting surface of the body.

9. The board of claim 8, wherein a marking pattern is provided on at least one surface of the body.

10. The board of claim 9, wherein the marking pattern is provided on at least one of two outermost ceramic layers disposed in outermost positions of the body among the plurality of ceramic layers stacked in the body.

11. The board of claim 9, wherein the marking pattern is provided on any one of two outermost ceramic layers disposed in outermost positions of the body among the plurality of ceramic layers stacked in the body, and a minimum separation distance between the internal coil and an outermost ceramic layer on which the marking is provided is greater than a minimum separation distance between the internal coil pattern and an outermost ceramic layer on which the marking pattern is not provided. 12 . The board of claim 9, wherein a color of the marking pattern is different from that of the body.

13. The board of claim 9, wherein unevenness is formed on a surface of the marking pattern.

14. The board of claim 8, wherein the ceramic layers contain ferrite.

15. A system comprising:
an inductor having a first coil axis and
a multilayer bead adjacently disposed with the inductor,
wherein the multilayer bead includes:
a body in which a plurality of ceramic layers are stacked;
a plurality of internal electrode patterns formed on the plurality of ceramic layers; and
first and second external electrodes formed on both end surfaces of the body and electrically connected to both ends of an internal coil formed by a combination of the plurality of internal electrode patterns, respectively,
wherein a stacking direction of the plurality of ceramic layers is perpendicular to both end surfaces of the body on which the first and second external electrodes are formed,
a second coil axis of the internal coil is parallel to a mounting surface of the body, and
the second coil axis is non-parallel with the first coil axis of the inductor.

16. The system of claim 15, wherein a marking pattern is provided on at least one surface of the body.

17. The system of claim 16, wherein the marking pattern is provided on at least one of two outermost ceramic layers disposed in outermost positions of the body among the plurality of ceramic layers stacked in the body.

18. The system of claim 16, wherein the marking pattern is provided on any one of two outermost ceramic layers disposed in outermost positions of the body among the plurality of ceramic layers stacked in the body, and a minimum separation distance between the internal coil and an outermost ceramic layer on which the marking pattern is provided is greater than a minimum separation distance between the internal coil and an outermost ceramic layer on which the marking pattern is not provided.

19. The system of claim 16, wherein a color of the marking pattern is different from that of the body.

20. The system of claim 16, wherein unevenness is formed on a surface of the marking pattern.
